(19) United States
(12) Patent Application Publication
(10) Pub. No.: US 2006/0091423 A1
(43) Pub. Date: May 4, 2006

(54) Layer fill for homogenous technology processing

(76) Inventor: Peter Poechmueller, Unterhaching (DE)

Correspondence Address: SLATER & MATSIL LLP, 17950 PRESTON ROAD, SUITE 1000, DALLAS, TX, 75252, US

(21) Appl. No.: 10/977,644

(22) Filed: Oct. 29, 2004

(51) Int. Cl. H01L 21/82; H01L 29/76

(52) U.S. Cl. 257/206; 257/207; 438/128; 438/129

(57) ABSTRACT

Spare transistors are formed in regions of a semiconductor device where functional transistors are not formed, providing uniformity in etch and polishing processes, and resulting in transistors with more uniform parameters on the semiconductor device. The spare transistors may not be electrically connected to other components on the device, or alternatively, the spare transistors may be connected to other components for use as spare transistors, for example. The gates of the spare transistors provide a homogeneous gate material layer, resulting in improved etch, polishing, and lithography processes for the semiconductor device.

### TECHNICAL FIELD

The present invention relates generally to the design and manufacture of semiconductor devices, and more particularly to a layer fill for improved uniformity of semiconductor device features formed by chemical mechanical polish and etch processes.

### BACKGROUND

Semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. There may be a plurality of transistors, memory devices, switches, conductive lines, diodes, capacitors, logic circuits, and other electronic components formed on a single die or chip.

The material layers typically comprise thin films of conductive, semiconductive, and insulating materials that are patterned and etched to form integrated circuits (IC's). Each material layer is patterned with a desired pattern, e.g., using a photoresist and/or hard mask as a mask while exposed portions of the material layer are etched away, using dry or wet etch processes, as examples.

In many integrated circuit designs, the various material layers are planarized before depositing subsequent material layers. Chemical-mechanical polishing (CMP) is typically used for global planarization of a semiconductor wafer, and to remove excess material from over certain topographical features, e.g., after an etch process, for example. In a CMP process, elevated features of a wafer are selectively removed, e.g., material from high elevation features is removed more rapidly than material at lower elevations, resulting in reduced topography. The process is referred to as “chemical-mechanical polishing” because material is removed from the wafer by mechanical polishing, assisted by chemical action.

A problem that occurs in some semiconductor device designs is non-uniformity of feature sizes across a wafer. It is important for etch processes and CMP processes to have a uniform effect on semiconductor devices during the fabrication process in some designs, so that the various devices formed thereon have uniform electrical parameters. A planar surface is also important to achieve depth of focus (DOF) for lithography processes. However, as shown in the prior art drawing of FIG. 1 in a cross-sectional view, some semiconductor devices 100 have regions 104 of densely-populated or closely-spaced transistor devices 108a that are spaced apart from regions 106 that may have less densely-populated or widely-spaced transistor devices 108b. In other designs, the closely-spaced transistor device 108a in one region 104 may be spaced apart from other closely-spaced devices 108a in other regions 104, (not shown in FIG. 1; see FIG. 2).

The semiconductor device 100 includes a workpiece 102. A gate oxide Gₒₓ is formed over the workpiece 102, and a gate G material is formed over the gate oxide Gₒₓ. The gate G material may comprise polysilicon and additional material layers, such as silicides, metals such as tungsten (W), and hard mask and/or etch stop materials, as examples. The gate G material and optionally, the gate oxide Gₒₓ, are patterned and etched to form transistors 108a and 108b having gates G. Different etch chemistries are typically used to etch the various materials used for the gate G material. After the gate G and the gate oxide Gₒₓ are etched, the workpiece 102 is doped with impurities, and optionally, the workpiece 102 may be annealed to form active areas in the workpiece 102, forming sources S and drains D of the transistors 108a and 108b, as shown.

During the etch process of the prior art semiconductor device 100, the gates G of the closely-spaced transistors 108a in region 104 may be etched less than the gates G of the widely-spaced transistors 108b in region 106. For example, if a wet etch process is used during the etch process to form the gates G in regions 104 and 106, because region 104 is more heavily loaded with gates G, there is more gate material in the etching chemical in region 104. Thus, regions 104 and 106 have different etch results and different etch speeds. For example, the closely-spaced transistors 108a may have gates G comprising a width w₁, and the widely-spaced transistors 108b may have gates G comprising a width w₂, wherein width w₂ is less than width w₁. Alternatively, or in combination therewith, the etch process may form closely-spaced transistors 108a having gates G with a height h₁ in region 104 and widely-spaced transistors 108b having a height h₂ in region 106, wherein height h₂ is less than height h₁.

Gates G for transistors 108a and 108b having different dimensions is undesirable in some semiconductor designs, because this results in the transistor gates G in region 104 having different electrical properties and characteristics than the transistor gates G in region 106. For example, the gates G in region 104 have a higher resistance than the gates G in region 106 having a reduced height h₂ and/or width w₂. As an example, if the gate G length (e.g., in a direction into and out of the paper) is designed to be 100 nm, and the gate length G is 95 nm in some areas and 105 nm in other areas, this results in a 10% difference in length, causing a 10% difference in electrical behavior of the transistors. A 10% difference may be a significant difference in some semiconductor device designs, for example. The dimensions of the gates G of transistors 108a and 108b is desired to be predictable, reproducible, and consistent for a single integrated circuit or semiconductor device 100 for acceptable device performance, in some applications.

Note also that if two closely-spaced regions 104 are spaced apart by a distance of about two or more gate G widths apart, for example, the transistor gates G at the edges of the closely-spaced regions 104 may be etched more than in the center of the closely-spaced regions 104, for example (not shown).

Another problem with the semiconductor device 100 shown in FIG. 1 is that during a CMP process, the wide spaces 110 between region 104 and region 106 may be dished, as shown, creating a depression 112. This is undesirable, because subsequent layers formed thereon may not be planar, degrading the DOF of lithography processes, and/or the thickness of a subsequently deposited layer, such as an insulating layer that conductive vias or lines may be formed in (not shown in FIG. 1; see FIG. 8) may be thicker over the dished area 112 than in other areas of the workpiece 102. This also produces a semiconductor device 100 having unpredictable performance and characteristics. Furthermore, because region 104 is loaded more with transistor gates G, less material may be removed from the top surface of the gates G in region 104 during the polish process than in region 106, resulting in closely-spaced transistors 108a having gates G with a height h₁ in region 104, and widely-spaced transistors 108b having a height h₂ in region 106, wherein height h₂ is less than height h₁. Alternatively, less material may be removed from the top surface of the gates G in region 106 than in region 104, for example, resulting in a height difference in the gates G.

Fill structures have been used in the past in an attempt to make the effects of etching and CMP processes more uniform. A top view of a prior art fill structure 120 is shown in FIG. 2. The fill structure 120 is formed in a gate material layer of the semiconductor device 100, e.g., in the same material layer the gates G of transistors 108 are formed in. The transistors gates G in regions 104a, 104b and 104c comprise finger-shaped gate material that extend over n-wells (see the top portion of region 104a) or p-wells (see region 104c) in which the active areas S/D are formed, as shown.

The fill structure 120 comprises a large sheet of gate material with holes or apertures 122 formed over active areas of the workpiece (not shown). The fill structure 120 is formed between regions 104a, 104b, and 104c of closely-spaced transistors 108 so that there is gate material present in areas 110 between the regions 104a, 104b, and 104c during an etch or CMP process. The semiconductor device 100 has a similar active area density over the entire device 100; hence, the apertures 122 are formed in the fill structure 120 over the active areas.

In some semiconductor device designs, the fill structure 120 shown in FIG. 2 is effective in improving the uniformity of the gates G of the semiconductor device 100. However, this prior art approach results in unused or wasted surface area of the semiconductor device 100. The fill structure 120 comprises large regions containing primarily gate material, which may result in uneven removal of more of the fill structure 120 being etched or polished away, compared to the gate G material. The fill structure 120 is not homogeneous enough to achieve a high yield in advanced technologies. Physical failure analysis (PFA) of such structures 120 has revealed failures within the fill structures 120 or in the vicinity of the transition area from the fill structure 120 to gates G which comprise the functional circuitry, due to planarization issues or critical dimension (CD) variation due to lithography proximity effects or etch process loading.

Thus, improved fill structures for achieving uniformity of gates of transistors of semiconductor devices are needed in the art.

### SUMMARY OF THE INVENTION

These and other problems are generally solved or circumvented, and technical advantages are generally achieved, by preferred embodiments of the present invention, which comprise novel fill structures of a gate material layer having substantially the same size and shape as the gates within the gate material layer. The fill structures provide uniform gate formation, and may be used to form spare transistors, if a design change is made to the semiconductor device, by modifying a conductive line level mask and/or via level mask.

In accordance with a preferred embodiment of the present invention, a semiconductor device includes a workpiece, the workpiece comprising a first region and a second region. A plurality of first transistors is disposed in the first region of the workpiece, the plurality of first transistors comprising functioning devices, at least a portion of one of the first transistors having a width comprising a first dimension. A plurality of second transistors is disposed in the second region of the workpiece, the plurality of second transistors comprising non-functioning devices, wherein each of the plurality of second transistors is spaced apart from a first transistor by a second dimension, wherein the second dimension comprises about five times the first dimension or less.

In accordance with another preferred embodiment of the present invention, a semiconductor device includes a plurality of functional transistor gates formed in a first region of a workpiece, each of the plurality of functional transistor gates having a width comprising a first dimension. At least one non-functional transistor gate is formed in a second region of the workpiece proximate the first region, the at least one non-functional transistor gate having a width comprising substantially the first dimension, wherein the non-functional transistor gate is disposed apart from the functional transistor gates by a dimension equal to or less than about five times the first dimension.

In accordance with yet another preferred embodiment of the present invention, a method of manufacturing a semiconductor device includes providing a workpiece, the workpiece comprising a first region and a second region, and forming a plurality of first transistors in the first region of the workpiece. The plurality of first transistors comprise functioning devices, and at least a portion of one of the first transistors has a width comprising a first dimension. A plurality of second transistors is formed in the second region of the workpiece, the plurality of second transistors comprising non-functioning devices. Each of the plurality of second transistors is spaced apart from a first transistor by a second dimension, wherein the second dimension comprises about five times the first dimension or less.

In accordance with another preferred embodiment of the present invention, a method of designing a semiconductor device includes determining a layout for a plurality of functional transistors, each of the plurality of functional transistors having at least one first gate, the layout having regions with no first gates disposed therein. Each at least one first gate comprises a width comprising a first dimension. A layout is determined for a plurality of non-functional transistors in the regions with no first gates disposed therein. Each of the plurality of non-functional transistors comprises at least one second gate having substantially the same dimensions as the at least one first gate and is spaced apart from the plurality of functional transistors by a second dimension. The second dimension comprises about five times the first dimension or less.

Advantages of embodiments of the present invention include providing a novel fill structure in a gate material layer simulating functional gate shapes, promoting a uniform etch and CMP environment for the gate material layer. A plurality of functional transistors having uniform resistance and other electrical parameters are produced by embodiments of the present invention. Because the planarity of the gate material layer is improved, the DOF of lithography processes is improved for subsequently deposited material layers of the semiconductor device. Advantageously, the novel fill structures may be used to form spare transistors, in some embodiments.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a prior art semiconductor device with gates having different dimensions due to etch or CMP processes;

FIG. 2 is a top view of a prior art fill structure for a gate material layer;

FIG. 3 shows a top view of a novel fill structure in accordance with an embodiment of the present invention implemented in the semiconductor device design shown in FIG. 2, wherein a plurality of non-functional transistor gate shaped structures is disposed between the functional transistor gates;

FIG. 4A shows an example of a semiconductor device design and a fill structure of the present invention included between adjacent transistor gates;

FIG. 4B illustrates that the fill structures of the present invention may be extended into functional gate region in accordance with embodiment of the invention to achieve a more homogeneous layer fill structure;

FIG. 5 illustrates a logic NAND gate that may be formed from transistors, in which the novel fill structure described herein may be implemented in;

FIG. 6 shows a schematic diagram of the NAND gate of FIG. 5, comprising four transistors;

FIG. 7 shows a top view of the NAND gate schematic of FIG. 6 implemented on a semiconductor workpiece and including non-functional transistor gates for layer fill structures in accordance with an embodiment of the present invention; and

FIG. 8 shows a cross-sectional view of a portion of the semiconductor device shown in FIG. 7.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

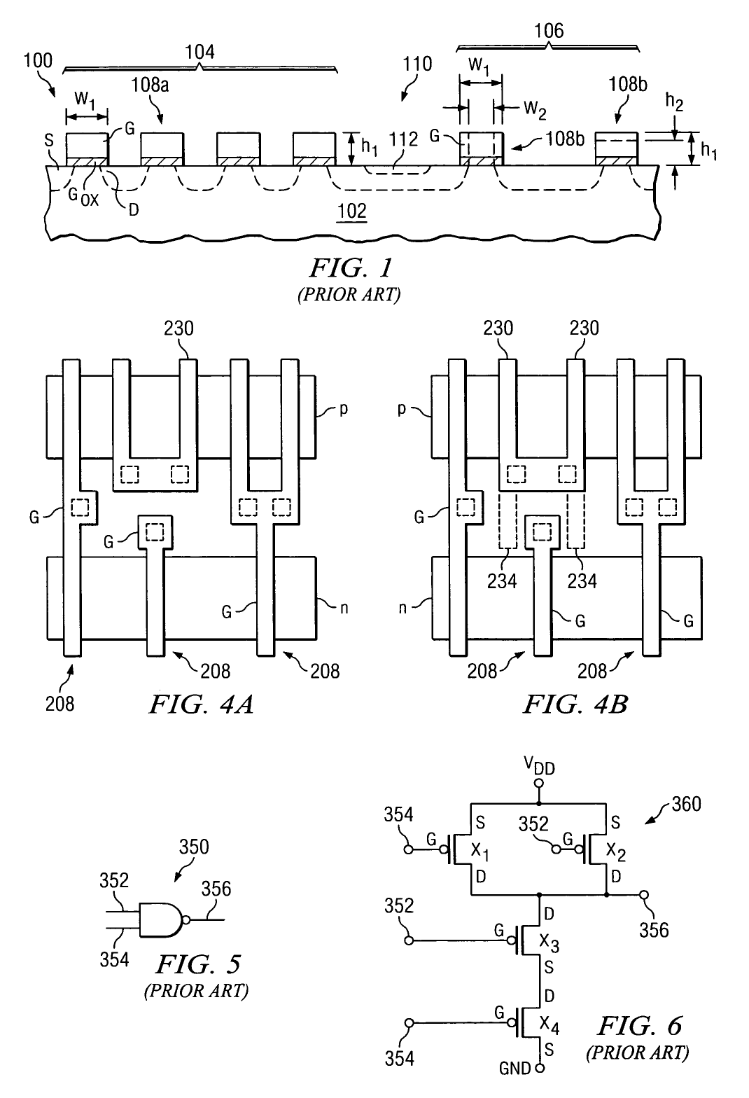

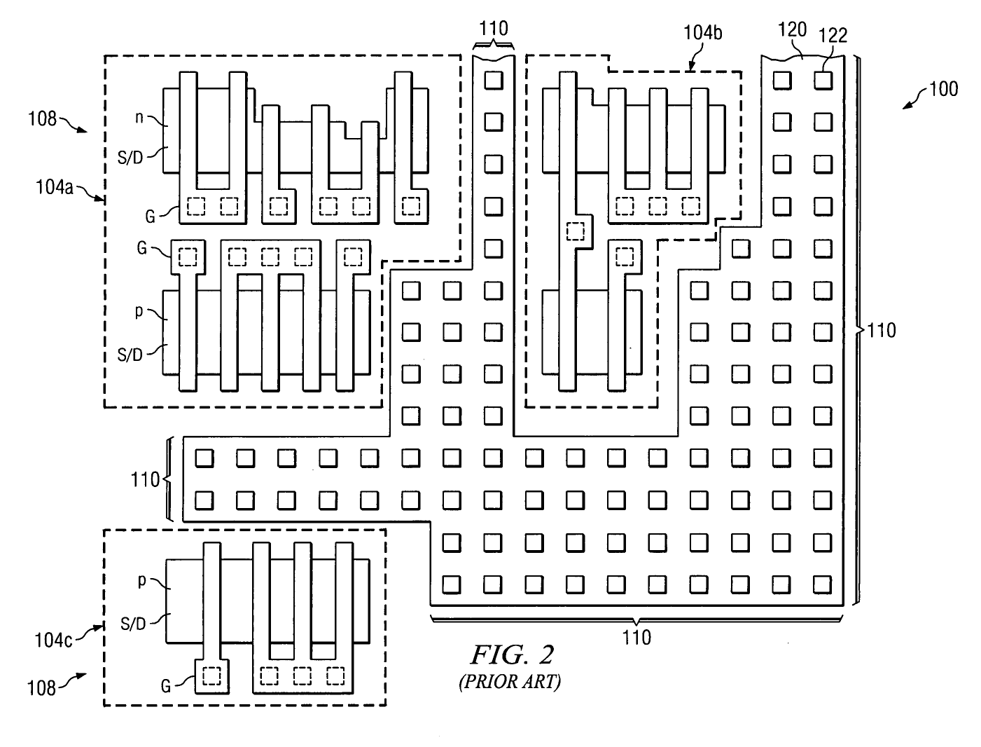

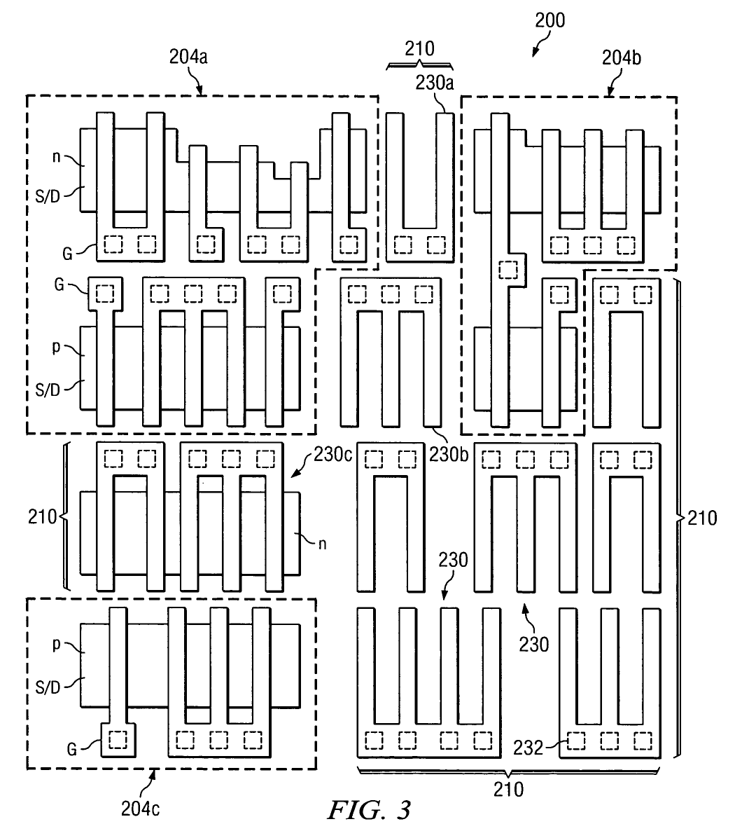

FIG. 3 shows a top view of a novel layer fill structure in accordance with an embodiment of the present invention implemented in the semiconductor device design shown in FIG. 2, e.g., having a plurality of blocks of functional transistor gates separated by wide spaces. Like numerals are used as reference numbers for the various elements shown as were used in FIGS. 1 and 2.

Regions 204a, 204b, and 204c have a plurality of functional gates G formed therein. The functional gates G comprise one or more fingers of polysilicon and other gate materials that extend over active areas S/D formed in n-wells or p-wells. The gate G design of FIG. 3 is the same as shown in FIG. 2, for example. However, in regions 210 between regions 204a, 204b, and 204c, novel non-functional gates 230 are formed to provide a homogeneous fill layer. The squares shown in phantom represent gate contacts used to connect the gates G or 230 to the next higher level or material layer.

Preferably, the non-functional gates 230 comprise substantially the same size and shape as at least one of the functional gates G. For example, the functional gates G may have a width comprising a minimum feature size of the semiconductor device 200. The non-functional gates 230 may also comprise the minimum feature size, and may comprise substantially the same length as the functional gates G. Preferably, the non-functional gates 230 are positioned away from each of the functional gates G by no greater than five times a width of a functional gate G, to provide a more even loading of the gate material layer for etching, polishing and subsequently deposited material layer lithography processes.

In one embodiment, each of the functional transistor gates G have a width comprising a first dimension, and the non-functional transistor gates 230 have a width comprising substantially the first dimension, wherein the non-functional transistor gate 230 is disposed apart from the functional transistor gates G by a dimension equal to or less than about five times the first dimension. In yet another embodiment, the non-functional transistor gates 230 are disposed apart from the functional transistor gates G by a dimension equal to or less than about two times the first dimension.

The non-functional gates 230 may comprise one or more fingers and are disposed over active areas of the semiconductor device 200, in one embodiment. For example, as shown in FIG. 3, non-functional gates 230a comprise two fingers, non-functional gates 230b comprise three fingers, and non-functional gates 230c comprise both two and three fingers. Preferably, the non-functional gates 230 are designed to fill the empty spaces 210 between the functional gates G, to provide a gate material layer having a homogenous structure. The shape of the non-functional gates 230 preferably mimic the shape and size of the functional gates G to provide the homogenous structure.

In one embodiment, the non-functional gates 230 are not electrically connected to other elements of the semiconductor device 200. However, in another embodiment, the non-functional gates 230 are preferably coupled to a constant voltage level, to prevent the non-functional gate 230 voltage level from floating. Preferably, the terminals of the non-functional gates 230 are connected to a fixed voltage level so that potential leakage or shorts due to mis-processing are minimized. For example, the non-functional gates 230 may be connected to a ground connection and a power supply connection.

FIG. 4A shows an example of a semiconductor device design and a fill structure comprising non-functional gates 230 of the present invention included between adjacent functional transistor gates G of transistors 208. In one embodiment of the present invention, the non-functional gates 230 may be extended into the regions of the functional gates G, as shown in phantom in FIG. 4B at 234. Thus, if the regions of functional gates G comprise empty areas with no functional gates formed therein, the non-functional gates 230 may be extended into those regions to provide a homogenous fill structure for the gate material layer. Preferably, the extensions 234 are disposed over non-active areas, e.g., preferably the extensions 234 are disposed over thick oxide disposed between two adjacent active areas.

Transistors are used in many different types of circuits. The novel layer fill structure described herein may be implemented in any semiconductor device design that includes transistor devices, for example. FIG. 5 illustrates a logic NAND gate 350 that may be formed from transistors, as an example. The NAND gate 350 includes a first input signal connection 352, a second input signal connection 354, and an output signal connection 356, as shown. FIG. 6 shows a schematic diagram 360 of the NAND gate of FIG. 5, comprising transistors X₁, X₂, X₃, and X₄. The first input signal connection 352 is coupled to the gate G of transistors X₂ and X₃, and the second input signal connection 354 is coupled to the gate G of transistors X₁ and X₄, as shown. The sources S of transistors X₁ X₂ are coupled to a voltage supply connection VDD, and the source of transistor X₄ is coupled to ground connection GND. The drains D of transistors X₁, X₂, and X₃ are coupled together at the output signal connection 356 and provide the output signal in response to the first and second input signals. The source S of transistor X₃ is coupled to the drain D of transistor X₄, as shown.

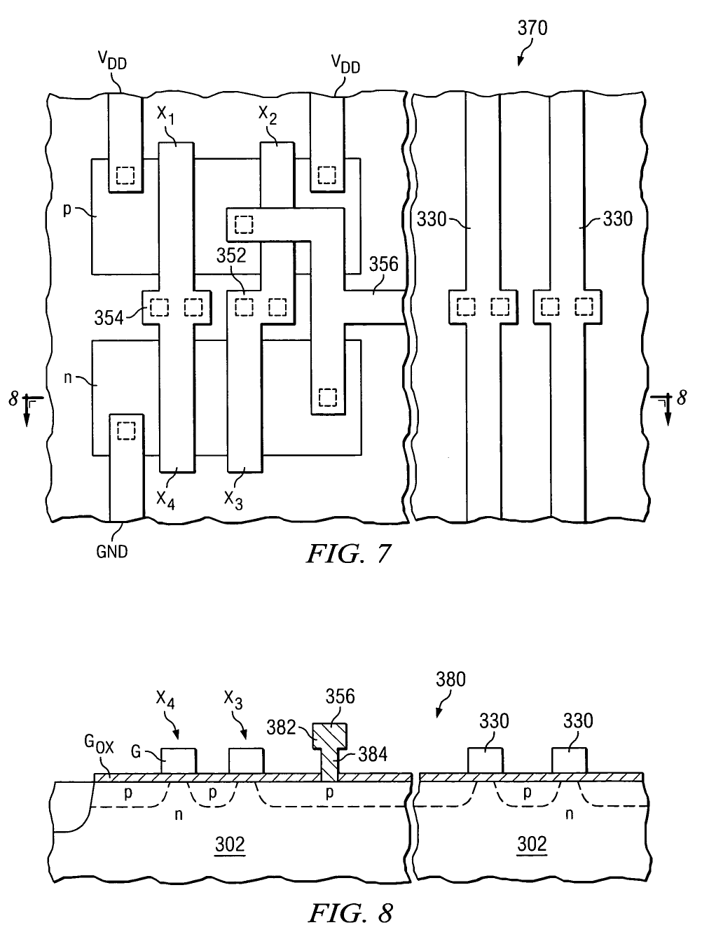

FIG. 7 shows a top view of a semiconductor device 370 comprising the NAND gate shown in the schematic 360 of FIG. 6 implemented on a semiconductor workpiece. FIG. 8 shows a cross-sectional view 380 of a portion of the semiconductor device 370 shown in FIG. 7. In FIG. 7, the gates G of the transistors are labeled X₁, X₂, X₃, and X₄. The ground connection GND and power supply connection VDD may comprise metallization e.g., formed in a metal layer disposed over the gate material layer. The output signal connection 356 may be wired using metallization 382 (see FIG. 8) formed in a metal layer, also. The metallization of the ground connection, power supply connection, and output signal connection 356 may be coupled to the active regions (e.g., the sources S and drains D) of the transistors X₁, X₂, X₃, and X₄ using a via (see via 384 in FIG. 8 coupled between the active region and the metallization 382 of the output signal 356.)

Non-functional transistors comprising gates 330 are formed in accordance with embodiments of the present invention to provide a homogenous fill structure for the gate material layer of the device 370, in regions where no functional transistors X₁, X₂, X₃, and X₄ are formed. The non-functional transistor gates 330 may be coupled to the ground connection GND and power supply connection VDD, or the non-functional transistor gates 330 may be allowed to float. A cross-sectional view of the non-functional transistor gates 330 is shown in FIG. 8. The non-functional transistors in accordance with embodiments of the present invention comprise a gate 330, gate oxide Gₒₓ and active regions comprising the source and drain comprised of p-type material that is implanted into an n-well (or alternatively, the active regions may comprise n-type material implanted into a p-well, not shown.)

Embodiments of the present invention include a semiconductor device having the non-functional transistors and gates 220 and 330 described herein formed in regions where no functional transistors are formed. Embodiments of the present invention also include a method of forming a semiconductor device having non-functional transistors formed thereon in regions where no functional transistors are formed. Referring to FIGS. 7 and 8, the method includes providing a workpiece 302, the workpiece 302 comprising a first region and a second region. The workpiece 302 may include a semiconductor substrate comprising silicon or other semiconductor materials that may be covered by an insulating layer, for example. The workpiece 302 may include active components or circuits formed therein, not shown. The workpiece 302 may comprise silicon oxide over single-crystal silicon, for example. The workpiece 302 may include other conductive layers or other semiconductor elements, e.g. transistors, diodes, etc. Compound semiconductors, GaAs, InP, Si/Ge, or SiC, as examples, may be used in place of silicon.

The method includes forming a plurality of first transistors X₁, X₂, X₃, and X₄ in the first region of the workpiece 302, the plurality of first transistors X₁, X₂, X₃, and X₄ comprising functioning devices, at least a portion of one of the first transistors X₁, X₂, X₃, and X₄ having a width comprising a first dimension. The method includes forming a plurality of second transistors having gates 330 in the second region of the workpiece 302, the plurality of second transistors comprising non-functioning devices, wherein the gates 330 of each of the plurality of second transistors is spaced apart from a first transistor X₁, X₂, X₃, and X₄ by a second dimension, wherein the second dimension comprises about five times the first dimension or less. The first dimension may comprise a minimum feature size of the semiconductor device. The gates G of the first transistors X₁, X₂, X₃, and X₄ and the gates 330 of the second transistors preferably are patterned using a single lithography mask.

In one embodiment, before forming the gates G, the method includes implanting the workpiece 302 with a first impurity to form an n-well, as shown in FIG. 8, although alternatively, a p-well may be formed; see FIG. 3. A gate oxide material Gₒₓ is formed over the workpiece 302, and a gate material is formed over the gate oxide material Gₒₓ. The gate material may comprise polysilicon, a metal, a silicide, a hard mask, an etch stop material, or combinations thereof, as examples, although alternatively, the gate material may comprise other materials. The gate material is patterned, e.g., using a single lithography mask to pattern the functional gates G and the non-functional gates 330, and portions of the workpiece between the gates G and 330 are implanted with a second impurity, the second impurity being different from the first impurity. For example, p regions may be formed in the n-wells, as shown in FIG. 8.

Semiconductor device designs typically comprise several design phases, and the lithography masks may be changed to correct problems found at each design phase or to make product improvements. For example, it is common for mask levels to be changed five or six times in a typical semiconductor device product design. Advantageously, the non-functional transistors 230 and 330 described herein may be used as spare transistors by changing the lithography mask for a metallization layer and optionally, a via layer. The metallization layer and via layer may be used to connect the non-functional transistors 230 and 330 to other transistors or components of the semiconductor device.

One embodiment of the present invention comprises a method of designing a semiconductor device. The method comprises determining a layout for a plurality of functional transistors, each of the plurality of functional transistors having at least one first gate, the layout having regions with no first gates disposed therein, each at least one first gate comprising a width comprising a first dimension. A layout is determined for a plurality of non-functional transistors in the regions with no first gates disposed therein, each of the plurality of non-functional transistors comprising at least one second gate having substantially the same dimensions as the at least one first gate and being spaced apart from the plurality of functional transistors by a second dimension, the second dimension comprising about five times the first dimension or less. The method may include fabricating the semiconductor device, testing the plurality of functional transistors, and connecting at least one of the plurality of non-functional transistors to function as a functional transistor. The previously non-functional transistor that now functions as a functional transistor may be used as a spare to replace a functional transistor, or as an additional functional transistor, as examples.

Having spare transistors in a semiconductor design is advantageous because only the metallization mask levels need to be changed in order to connect the spare transistors in the semiconductor device, making them functional transistors. If no spare transistors are included in the design, the entire mask set may be required to be changed, which is costly. Alternatively, if additional transistors are required in the design, the die size may be required to be increased, which can be extremely problematic, requiring a substantial design change and new probe card designs, as examples.

Preferably about 5% or greater of the topography of a semiconductor device comprises non-functional transistors 230 or 330 in order to achieve a homogeneous layout while simultaneously providing spare transistors, in accordance with an embodiment of the present invention. Also, preferably there are no large areas without gate material within the gate material layer design; the non-functional gates 230 and 330 preferably fill in substantially all of the wide spaces between functional gates to provide an improved layer fill for homogenous technology processing.

Advantages of embodiments of the invention include providing a novel fill structure simulating the functional transistor gate shapes, promoting a uniform etch and CMP environment for the gate material layer. A plurality of transistors having uniform resistance and other uniform electrical parameters are produced by embodiments of the present invention. Advantageously, the novel fill structures may be used to form spare transistors, in some embodiments. The improved planarity results in improved lithography processes for subsequently formed layers, resulting in improved DOF.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a workpiece, the workpiece comprising a first region and a second region;
a plurality of first transistors disposed in the first region of the workpiece, the plurality of first transistors comprising functioning devices, at least a portion of one of the first transistors having a width comprising a first dimension; and
a plurality of second transistors disposed in the second region of the workpiece, the plurality of second transistors comprising non-functioning devices, wherein each of the plurality of second transistors is spaced apart from a first transistor by a second dimension, wherein the second dimension comprises about five times the first dimension or less.

2. The semiconductor device according to claim 1, wherein the semiconductor device comprises a ground connection and a power supply connection, wherein each of the plurality of second transistors is coupled to the ground connection and the power supply connection of the semiconductor device.

3. The semiconductor device according to claim 1, wherein the second dimension comprises about two times the first dimension or less.

4. The semiconductor device according to claim 1, wherein the first dimension comprises a minimum feature size of the semiconductor device.

5. The semiconductor device according to claim 4, wherein each of the plurality of first transistors comprises a first gate, wherein the first gates comprise the minimum feature size, and wherein each of the plurality of second transistors comprises a second gate, the second gate comprising the minimum feature size.

6. The semiconductor device according to claim 5, wherein a portion of at least one of the second gate extends into the first region proximate a first gate.

7. A semiconductor device, comprising:
a plurality of functional transistor gates formed in a first region of a workpiece, each of the plurality of functional transistor gates having a width comprising a first dimension; and
at least one non-functional transistor gate formed in a second region of the workpiece proximate the first region, the at least one non-functional transistor gate having a width comprising substantially the first dimension, wherein the non-functional transistor gate is disposed apart from the functional transistor gates by a dimension equal to or less than about five times the first dimension.

8. The semiconductor device according to claim 7, wherein the non-functional transistor gate is disposed apart from the functional transistor gates by a dimension equal to or less than about two times the first dimension.

9. The semiconductor device according to claim 7, wherein the semiconductor device comprises a ground connection and a power supply connection, wherein the at least one non-functional transistor gate comprises a gate of a non-functional transistor, wherein each at least one non-functional transistor is coupled to the ground connection and the power supply connection of the semiconductor device.

10. The semiconductor device according to claim 7, wherein the first dimension comprises a minimum feature size of the semiconductor device.

11. The semiconductor device according to claim 7, wherein a portion of at least one non-functional transistor gate extends into the first region proximate a functional transistor gate.

12. A method of manufacturing a semiconductor device, the method comprising:
providing a workpiece, the workpiece comprising a first region and a second region;
forming a plurality of first transistors in the first region of the workpiece, the plurality of first transistors comprising functioning devices, at least a portion of one of the first transistors having a width comprising a first dimension; and
forming a plurality of second transistors in the second region of the workpiece, the plurality of second transistors comprising non-functioning devices, wherein each of the plurality of second transistors is spaced apart from a first transistor by a second dimension, wherein the second dimension comprises about five times the first dimension or less.

13. The method according to claim 12, wherein the first dimension comprises a minimum feature size of the semiconductor device.

14. The method according to claim 12, wherein forming the plurality of second transistors comprises forming the second transistors such that the second dimension comprises about two times the first dimension or less.

15. The method according to claim 12, further comprising forming a ground connection and a power supply connection, and connecting each of the plurality of second transistors to the ground connection and the power supply connection of the semiconductor device.

16. The method according to claim 12, wherein forming each of the plurality of first transistors comprises forming the plurality of first transistors comprising a first gate, the first gate comprising a width comprising the first dimension, wherein forming each of the plurality of second transistors comprises forming a second gate, the second gate comprising the first dimension.

17. The method according to claim 16, wherein the first dimension comprises a minimum feature size of the semiconductor device.

18. The method according to claim 16, wherein forming the plurality of first transistors and forming the plurality of second transistors comprises depositing a gate material, and patterning the gate material using a single lithography mask.

19. The method according to claim 18, wherein forming the plurality of first transistors and forming the plurality of second transistors comprises etching the gate material, wherein the second gates of the plurality of second transistors causes the formation of the first gates of the plurality of first transistors to have substantially uniform dimensions.

20. The method according to claim 19, wherein forming the plurality of second transistors comprises extending the second gates into the first region proximate the first gates.

21. The method according to claim 12, wherein forming the plurality of first transistors in the first region of the workpiece and forming the plurality of second transistors in second region of the workpiece comprises:
implanting the workpiece with a first impurity;
forming a gate oxide material over the workpiece;
forming a gate material over the gate oxide material;
patterning the gate material; and
implanting exposed portions of the workpiece with a second impurity, the second impurity being different from the first impurity.

22. The method according to claim 21, wherein depositing the gate material comprises forming polysilicon, a metal, a silicide, a hard mask, an etch stop material, or combinations thereof.

23. A method of designing a semiconductor device, the method comprising:
determining a layout for a plurality of functional transistors, each of the plurality of functional transistors having at least one first gate, the layout having regions with no first gates disposed therein, each at least one first gate comprising a width comprising a first dimension; and
determining a layout for a plurality of non-functional transistors in the regions with no first gates disposed therein, each of the plurality of non-functional transistors comprising at least one second gate having substantially the same dimensions as the at least one first gate and being spaced apart from the plurality of functional transistors by a second dimension, the second dimension comprising about five times the first dimension or less.

24. The method according to claim 23, further comprising:
coupling each of the plurality of non-functional transistors to a ground connection and a power supply connection of the semiconductor device.

25. The method according to claim 23, further comprising:
fabricating the semiconductor device;
testing the plurality of functional transistors; and
connecting at least one of the plurality of non-functional transistors to function as a functional transistor.

26. The method according to claim 25, wherein connecting at least one of the plurality of non-functional transistors to function as a functional transistor comprises changing a lithography mask for a metallization layer for a conductive line layer of the semiconductor device, to connect a conductive line to the at least one non-functional transistor.

27. The method according to claim 26, wherein connecting at least one of the plurality of non-functional transistors to function as a functional transistor further comprises changing a lithography mask for a metallization layer for a via layer of the semiconductor device, to connect a via to the at least one non-functional transistor.
